(19) United States
(12) Patent Application Publication
(10) Pub. No.: US 2025/0374484 A1
(43) Pub. Date: Dec. 4, 2025

(54) ULTRAFAST THERMAL SWITCH

(71) Applicant: BOARD OF REGENTS, THE UNIVERSITY OF TEXAS SYSTEM, Austin, TX (US)

(72) Inventors: Xianming Dai, Austin, TX (US); Li Shan, Austin, TX (US)

(21) Appl. No.: 19/107,986

(22) PCT Filed: Aug. 31, 2023
(86) PCT No.: PCT/US2023/073221

§ 371 Date: Feb. 28, 2025

Related U.S. Application Data
(60) Provisional application No. 63/374,010, filed on Aug. 31, 2022.
(60) Provisional application No. 63/379,893, filed on Oct. 17, 2022.

(51) Int. Cl. H05K 7/20

(52) U.S. Cl. CPC H05K 7/20327; H05K 7/20309; H05K 7/20318

(57) ABSTRACT

A thermal switch includes a cooling liquid reservoir, an acoustic droplet generator, and an array of micro-nozzles. A control signal can indicate to the acoustic droplet generator to generate an acoustic wave which pushed cooling liquid from the cooling liquid reservoir through the array of micro-nozzles. The micro-nozzles utilize an inverted geometry where the entrance is larger than the exit to cause an increase in pressure to allow a specific amount of cooling liquid to be released as a droplet. The droplets from the array of micro-nozzles form a droplet array on a heat component thereby allowing a thermal energy transfer to take place, where the thin liquid film absorbs the thermal energy and changes state to a vapor. The heat component can be a heat sink, a chip, an integrated circuit, or other type of component.

### CROSS-REFERENCE TO RELATED APPLICATION

This application claims the benefit of U.S. Provisional Application Ser. No. 63/374,010 filed Aug. 31, 2022, by Xianming Dai and Li Shan, entitled “ULTRAFAST THERMAL SWITCH” and U.S. Provisional Application Ser. No. 63/379,893 filed Oct. 17, 2022, by Xianming Dai and Li Shan, entitled “ULTRAFAST THERMAL SWITCH AND APPLICATION THEREOF”, commonly assigned with this application and incorporated herein by reference in their entirety.

### TECHNICAL FIELD

This application is directed, in general, to improving control of a temperature of a surface and, more specifically, to using evaporative cooling to achieve the same.

### BACKGROUND

In cooling integrated circuits, chips, or other devices, current methods use water boiling or bulk spray techniques to deliver cooling liquids which land on the heat component allowing the thermal energy to be absorbed and carried away by the resulting vapor. The amount of energy needed to control these thermal switches is significant and they lack fine tune control to optimize the thermal energy transfer process to maximize the efficiency of the system. For example, a bulk spray or boiling technique allows cooling liquid to gather on the surface of the heat component so that when the spray is turned off, there is residual cooling that takes place. That unknown amount of residual cooling can lead to inefficiency in the cooling system.

### BRIEF DESCRIPTION

Reference is now made to the following descriptions taken in conjunction with the accompanying drawings, in which:

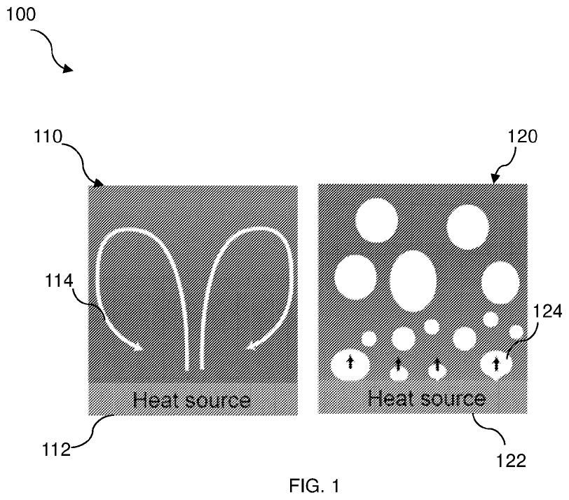

FIG. 1 is an illustration of a diagram of example conventional phase methods for increasing heat transfer;

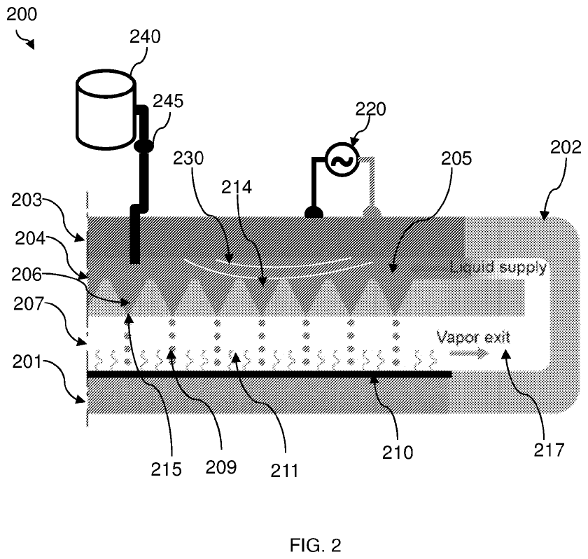

FIG. 2 is an illustration of a diagram of an example schematic of a thermal switch system designed, manufactured, or operated according to one or more embodiments of the disclosure;

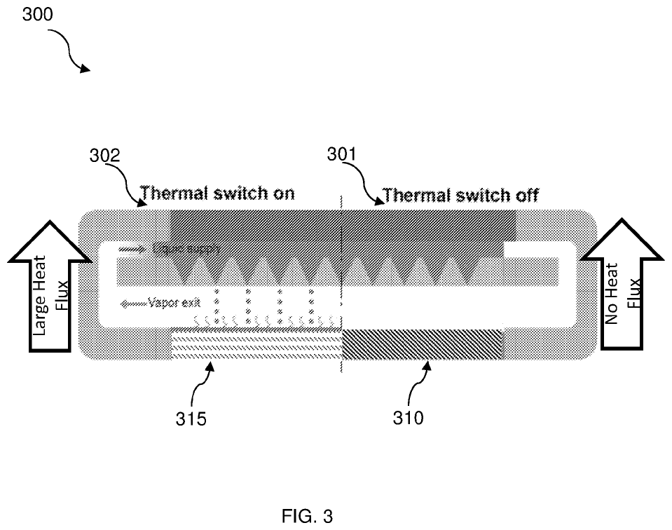

FIG. 3 is an illustration of a diagram of an example schematic demonstrating a thermal switch system in an on state and an off state and designed, manufactured, or operated according to one or more embodiments of the disclosure;

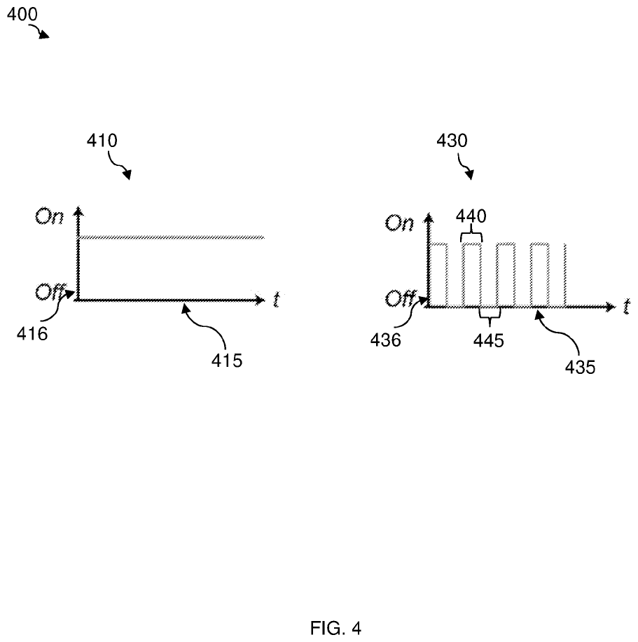

FIG. 4 is an illustration of a diagram of example line graphs demonstrating operational modes of a thermal switch system designed, manufactured, or operated according to one or more embodiments of the disclosure;

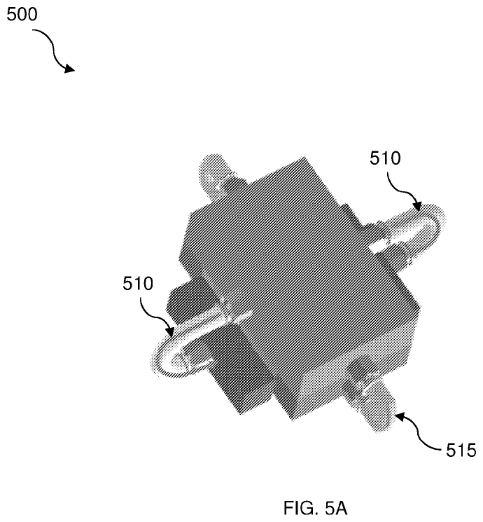

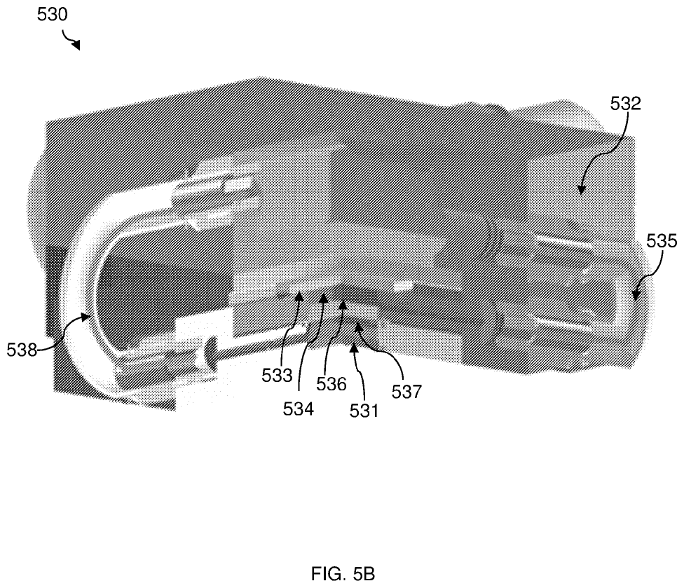

FIG. 5A is an illustration of a diagram of an example thermal switch assembly designed, manufactured, or operated according to one or more embodiments of the disclosure;

FIG. 5B is an illustration of a diagram of an example three-quarter view of the thermal switch assembly of FIG. 5A;

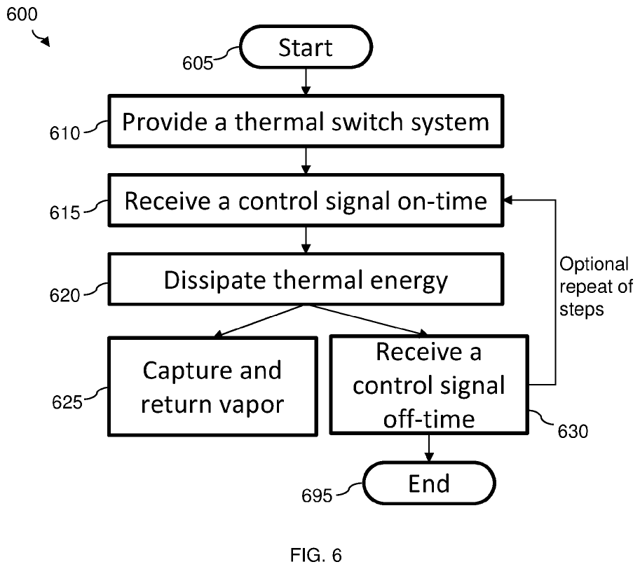

FIG. 6 is an illustration of a block diagram of an example method for implementing a thermal switch system designed, manufactured, or operated according to one or more embodiments of the disclosure;

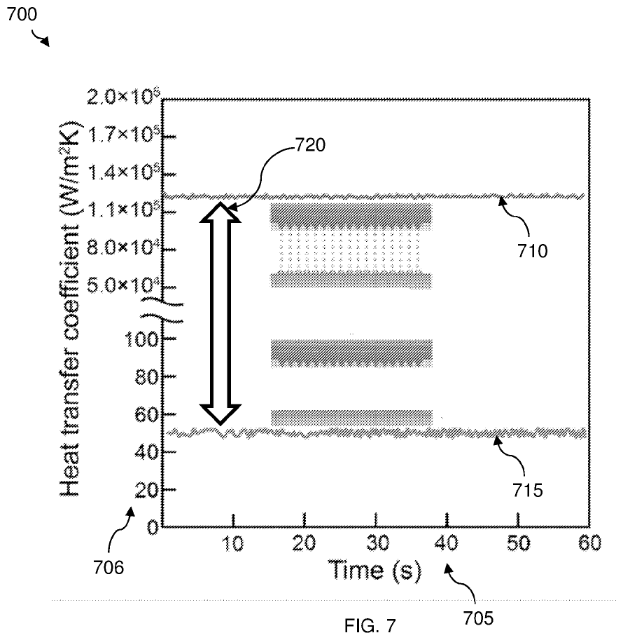

FIG. 7 is an illustration of a graph of an example heat transfer coefficient between an on-time and an off-time;

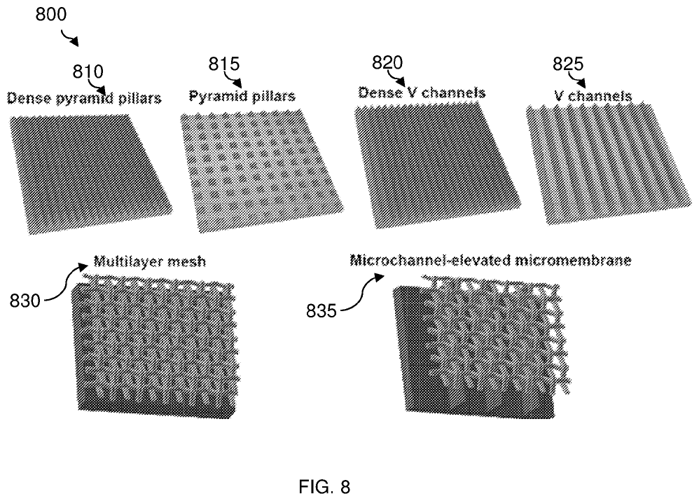

FIG. 8 is an illustration of diagrams of example arrays of micro-nozzles;

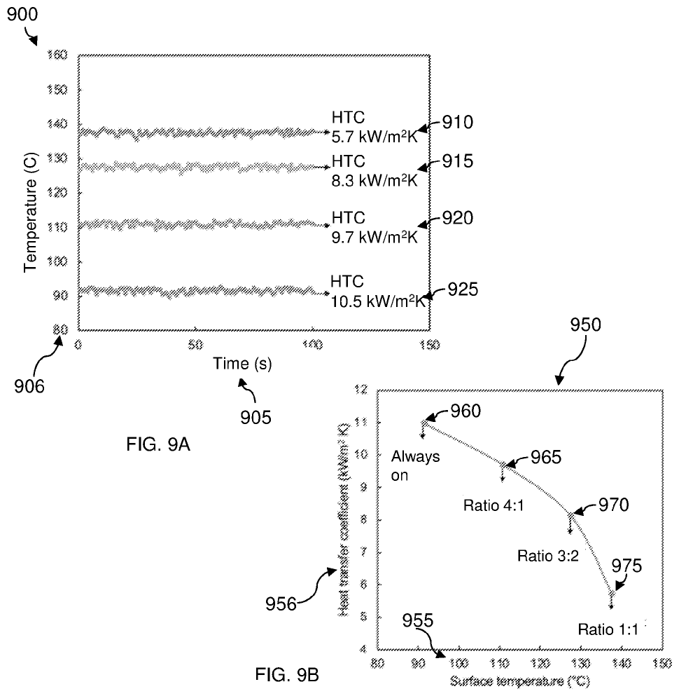

FIG. 9A is an illustration of a graph of an example temperature maintenance over time;

FIG. 9B is an illustration of a graph of an example on-time to off-time ratio;

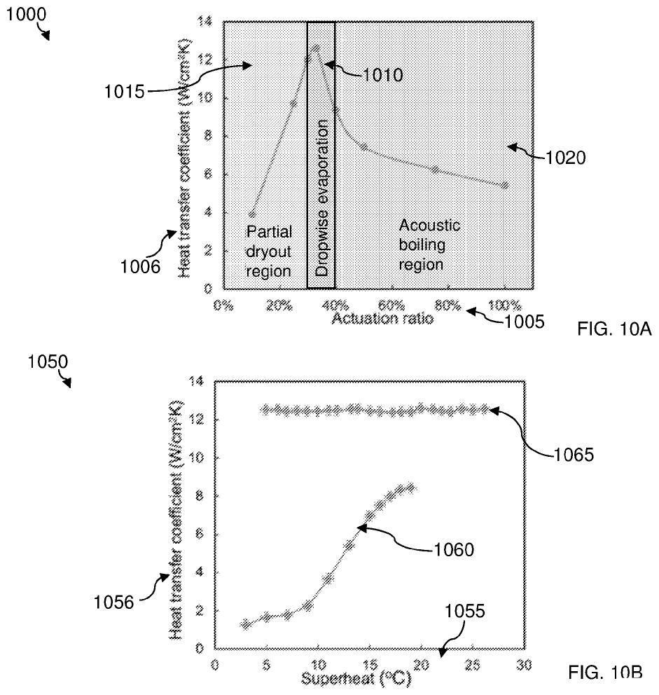

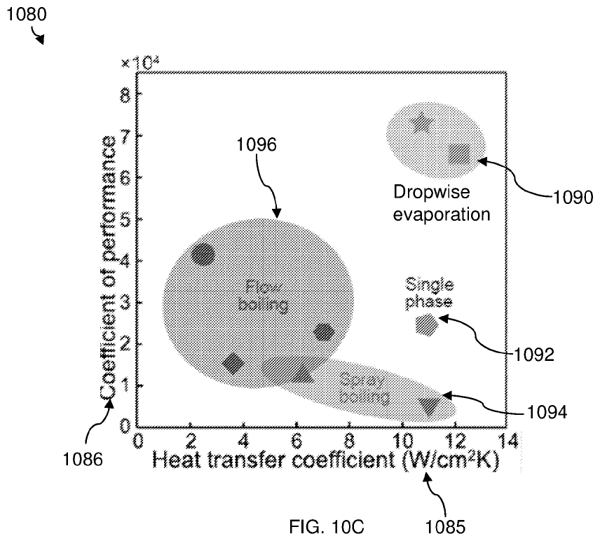

FIG. 10A is an illustration of a graph of an example optimal actuation ratio;

FIG. 10B is an illustration of a graph of an example comparison between dropwise evaporation and acoustic boiling;

FIG. 10C is an illustration of a graph of an example graph showing a heat transfer coefficient to a coefficient of performance;

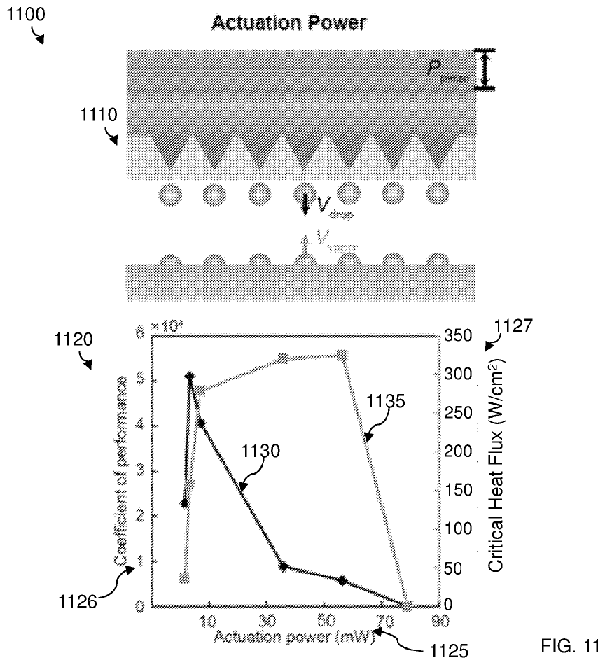

FIG. 11 is an illustration of a diagram of an example actuation power comparison;

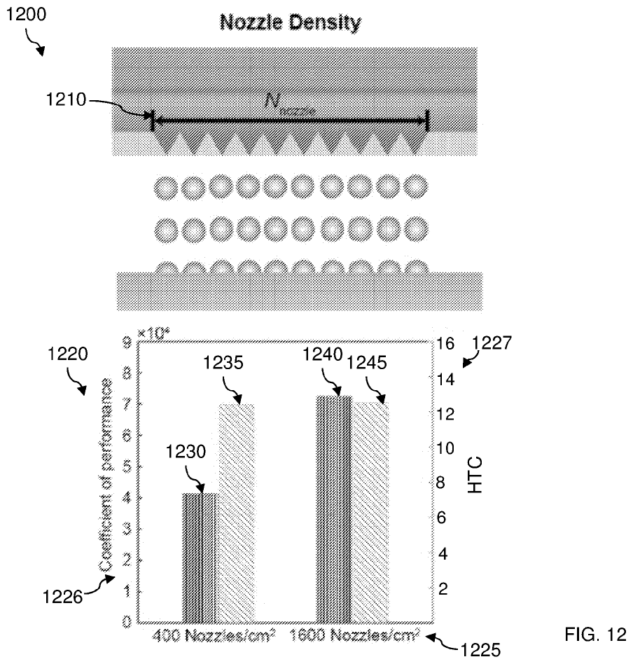

FIG. 12 is an illustration of a diagram of an example micro-nozzle density comparison; and

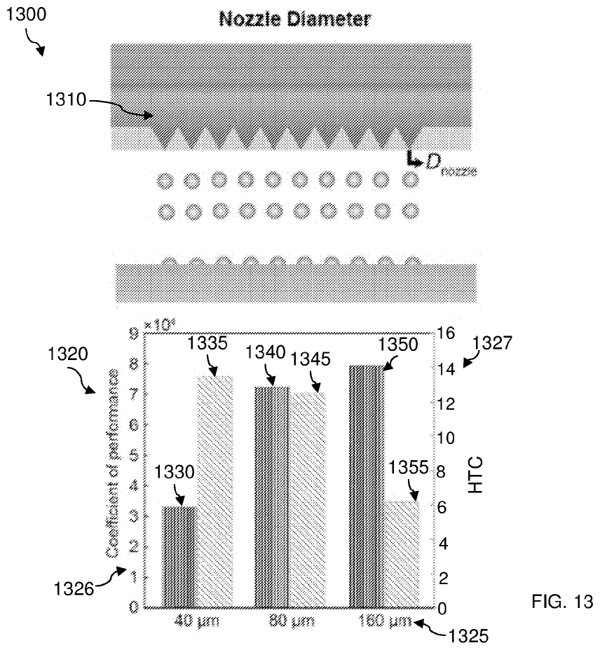

FIG. 13 is an illustration of a diagram of an example micro-nozzle diameter comparison.

### DETAILED DESCRIPTION

It is important to cool certain devices or components, such as computer chips, integrated circuits, or other small scale components. Excess heat (e.g., thermal energy) can reduce the efficiency or lifespan of the component. Cooling these components can be accomplished using a heat sink, a fan, or a type of cooling liquid. A heat transfer coefficient (HTC) (e.g., a thermal transfer coefficient) is an important measure in how well the cooling system works. The HTC is higher when the energy expended to produce the necessary cooling is lower. Energy efficient methods will result in a higher HTC.

In some applications, heat sinks and fans do not have a sufficiently high HTC. In these applications, cooling liquid methods, such as single-phase or spray boiling techniques, can achieve a higher HTC. However, the current single-phase or spray boiling techniques lack the ability of exactly determining the amount of cooling liquid that is being made available for the thermal energy absorption. For example, once a spray boiling nozzle is turned off, it may take time for the spray to fully shut down and there remains cooling liquid in the system and additional cooling can take place. This makes it difficult to maintain a precise temperature of the component. This can also increase costs as additional time, energy, and cooling liquid would need to be expended to maintain a certain temperature of the component.

In this disclosure, a thermal switch is presented that allows a specific amount (e.g., a precise amount) of cooling liquid to be released, where the release of the cooling liquid can be shut off very quickly. This allows a known quantity of cooling liquid to form a thin liquid film on the surface of the component and a known HTC to take place as the cooling liquid absorbs the heat and changes state to vapor. The amount of cooling liquid used can be reduced or better controlled as compared to conventional methods, and thereby results in a reduction in energy used as well. In some aspects, the disclosed thermal switch can be utilized within or as part of an integrated circuit. In some aspects, a specified range of temperatures may be needed that are not too high nor too low, for example, applications within a data center, an EV battery system, a LED lighting system, or a satellite system.

Using water as the cooling liquid, when the thermal switch is on, the heat flux can increase quickly with the surface temperature of the component (e.g., heat component). For example, in tests it can reach 1400 kilowatts per meters squared (kW/m²) at 150° Celsius (C). The HTC of the thin liquid film evaporation increases when the surface temperature is below 120° C. with a maximum HTC of 13 kW/cm² Kelvin (K). The HTC then decreases with the surface temperature due to the large temperature difference between the water and the component.

When the thermal switch is off, in testing, a low heat flux of 19±5 kW/m² can be achieved at all surface temperatures due to the limitation of natural convection. The heat flux can be 70 times lower than that at the switch-on state. It has a low HTC of 0.2±0.5 kW/m²K, which is 2400 times lower than that at the switch-on state.

In some testing, the thermal switch was turned on (on-time) and off (off-time) with an operation time of tₒₙ=30 seconds(s) and t_{off}=10 s. As the thermal switch is turned on, the temperature quickly decreases and reaches an equilibrium state at 27 s. The surface temperature decreased 28° C. when the thermal switch is on. The HTC was tested at 55 times higher at this state. As the thermal switch turned off again, the temperature quickly increases back to the initial temperature in about 10 s. The fast thermal response of the dropwise evaporation allows the quick heat dissipation of the heating surface.

In testing, accurate temperature and HTC control can be achieved by adjusting the operating time to the millisecond range. By adjusting the on-time and off-time ratio of the thermal switch, different surface temperatures and heat transfer coefficients can be achieved. For example, the heat transfer coefficient can be targeted to 5.7 kW/m²K at a temperature of 115° C. when operating the thermal switch at tₒₙ=25 milliseconds (ms) and t_{off}=25 ms. The HTC can increase up to 10.5 kW/m²K when the thermal switch is always on.

Turning now to the figures, FIG. 1 is an illustration of a diagram of example conventional phase 100 methods for increasing heat transfer. Conventional phase 100 shows a single-phase 110 method for conveying thermal energy 114 from a heat component 112. Conventional phase 100 shows a boiling phase 120 method for conveying thermal energy from a heat component 122 using cooling liquid 124. Single-phase 110 and boiling phase 120 use significant power to operate. They can leave residual cooling liquid on the respective heat components which can waste cooling liquid if not needed. When these systems are switched off, cooling can continue which can impact the efficiency of the components operating behind the heat component or impact the efficiency of the cooling system. In some aspects, the surface of heat component 112 can be of various materials, such as silicon, copper, aluminum, or various combinations thereof. In some aspects, the surface of heat component 112 can be flat, rough, porous structures, or various combinations thereof.

FIG. 2 is an illustration of a diagram of an example schematic of a thermal switch system 200 designed, manufactured, or operated according to one or more embodiments of the disclosure. A thermal switch system should have a large heat transfer coefficient when it is active. Conventional phase methods, such as shown in FIG. 1 (e.g., single phase cooling and spray boiling), have limited heat transfer behavior. Thermal switch system 200 utilizes dropwise evaporation on a heated surface by actively generating fine droplets via an acoustic droplet generator, i.e., acoustic atomization, and transporting them to the heated surface.

Thermal switch system 200 includes an acoustic droplet generator 203, a cooling liquid reservoir 204, and an array of micro-nozzles 206. Acoustic droplet generator 203, and array of micro-nozzles 206 comprise at least a portion of the components of a thermal switch apparatus. Optional to the thermal switch system is an electrical current system 220 (e.g., an alternate current (AC) system that can generate a sinuous wave or control signal) which can provide control signals to acoustic droplet generator 203. Acoustic droplet generator 203 can be an atomizer, an acoustic wave generator, a piezoelectric layer, or other type of generator. Acoustic droplet generator 203 can acoustically force the cooling liquid from the cooling liquid reservoir through array of micro-nozzles 206. In some aspects, a control signal can be received as an electric current to activate the piezoelectric ceramic layer.

The cooling liquid can be water, a water based liquid (e.g., water with additives), a dielectric fluid, an oil, a refrigerant, a mixed liquid, a compound, or various combinations thereof. In some aspects, the cooling liquid can be water and the thermal switch system employs cold plate cooling. In some aspects, the cooling liquid can be a dielectric liquid and the thermal switch system employs embedded cooling. The size of the opening of each micro-nozzle in array of micro-nozzles 206 can be determined to deliver a specific amount of cooling liquid, thereby improving efficiency of the thermal switch system 200. For example, a micro-nozzle diameter of 14 micrometers can be utilized, as well as other diameter sizes, smaller or larger.

When a control signal is received, for example from electrical current system 220, acoustic droplet generator 203 can generate acoustic waves 230 which propagate through the cooling liquid reservoir. When the acoustic waves reach each micro-nozzle entrance 214 of array of micro-nozzles 206, the acoustic waves can be focused by the inverted geometry of each micro-nozzle and form a large pressure gradient at a micro-nozzle exit 215. Inverted geometry means in this disclosure that the micro-nozzle entrance 214 is larger than micro-nozzle exit 215. The inverted geometry of each micro-nozzle can be a triangular pyramid geometry, a cone geometry, a tetrahedron geometry, or other types of geometries that can focus or concentrate the acoustic waves.

Subsequently, small droplets 209 (e.g., cooling liquid) can be ejected from the micro-nozzle into an evaporation chamber 207. Small droplets 209 can be forced to eject from each micro-nozzle and spray on a heat component 201. A thin liquid film 210 can be formed on the surface of heat component 201, which can have a large evaporation rate. The fast evaporation of thin liquid film 210 can lead to a larger heat transfer coefficient and a quick heat dissipation on the surface of heat component 201 by vapor 211 (e.g., vapor 211 is the result of a thermal transfer from heat component 201 to thin liquid film 210). Vapor 211 can travel through a vapor return path 217 to cooling liquid reservoir 204. In some aspects, a condenser 202 can be part of thermal switch system 200. Condenser 202 can receive vapor 211 from evaporation chamber 207, condensing vapor 211 to cooling liquid (e.g., condensed cooling liquid). In some aspects, the cooling liquid can be returned to cooling liquid reservoir 204. In some aspects, the cooling liquid can be returned to a cooling liquid tank 240.

In some aspects, heat component 201 can be part of or a whole of an integrated circuit. In some aspects, heat component 201 can be a heat sink or other type of thermal conductor conducting thermal transfer from another component to thermal switch system 200. In some aspects, thermal switch system 200 can be part of or wholly integrated with an integrated circuit or computer chip. In some aspects, thermal switch system 200 can be a separate component and adjacent to a device that generates heat.

In some aspects, cooling liquid tank 240 can be part of thermal switch system 200. Cooling liquid tank 240 can store additional quantities of cooling liquid and resupply or refill cooling liquid reservoir 204. In some aspects, a pump 245 can be part of thermal switch system 200. Pump 245 can pump cooling liquid from cooling liquid tank 240 to cooling liquid reservoir 204. In some aspect, one or more additional pumps can be included to move the cooling liquid or vapor 211 through the appropriate tubes or paths. In some aspects, a fan can be included to move vapor 211 through vapor return path 217. In some aspects, more than one array of micro-nozzles can be employed. In some aspects, the various arrays of micro-nozzles can utilize the same or separate cooling liquid reservoirs.

FIG. 3 is an illustration of a diagram of an example schematic demonstrating a thermal switch system 300 in an on state and an off state. A thermal switch system for thermal management has two operation states: an on state and an off state. When the thermal switch system is off (a state 301), no droplets of cooling liquid are ejected from the array of micro-nozzles due to lack of acoustic waves from the acoustic droplet generator, for example, a piezoelectric ceramic layer. The heat dissipation from the heat component 310 relies on natural convection, which results in negligible or a small heat flux and a low heat transfer coefficient (e.g., a small thermal transfer coefficient).

When the thermal switch system is on (a state 302), the acoustic droplet generator can be actuated by a control signal and fine droplets can be ejected from the array of micro-nozzles. The large evaporation rate of the liquid film offers a larger thermal transfer and improved heat dissipation of the heat component 315 as compared to state 301. A larger heat transfer (e.g., a large heat flux) coefficient can be achieved (e.g., a large thermal transfer coefficient) than in state 301.

FIG. 4 is an illustration of a diagram of example line graphs 400 demonstrating operational modes of a thermal switch system. When the thermal switch system is on, periodic control signals can be applied to the acoustic droplet generator. Droplets of cooling liquid can be ejected from the array of micro-nozzles due to the focused acoustic waves. By adjusting the control signal (e.g., actuation signal), the thermal switch behavior can be fine-tuned to provide specific amount of thermal transfer capability.

In some aspects, when a continuous control signal is applied to the acoustic droplet generator, the droplets can be ejected from the array of micro-nozzles at a maximum mass flow rate and a high heat transfer coefficient can be achieved, such as shown in line graph 410. Line graph 410 has an x-axis 415 showing the increase in time t. Line graph 410 has a y-axis 416 showing the droplet state as either on or off.

In some aspects, when no control signal is applied to the acoustic droplet generator the thermal switch system is in the off state. Droplets are not ejected from the array of micro-nozzles and a low heat transfer coefficient is achieved.

In some aspects, when a moderate cooling performance is needed for the heating component, an intermittent cooling mode can be used by adjusting the control signal's duty cycle as shown in line graph 430. In this mode, the control signal is turned off for a certain amount of time (off-time) (t_{off} 445) after a period of operation (on-time) (tₒₙ 440). By adjusting the time of tₒₙ in ratio to t_{off}, a precise control of the temperature of the heat component and of the heat transfer coefficient can be achieved. Line graph 430 has an x-axis 435 showing the increase in time t. Line graph 430 has a y-axis 436 showing the on or off state of the thermal switch.

FIG. 5A is an illustration of a diagram of an example thermal switch assembly 500. Thermal switch assembly 500 is an example implementation of the disclosure and shows one possible orientation of the various features. Thermal switch assembly 500 has two cooling liquid flows 510 to the cooling liquid reservoir. A vapor return path 515 allows the capture vapor to be condensed and returned to a cooling liquid tank. Thermal switch assembly 500 can be located next to, adjacent, or part of another component for which heat needs to be dissipated, such as an integrated circuit, a central processing unit, a graphics processing unit, or other types of devices or computer chips.

FIG. 5B is an illustration of a diagram of an example three-quarter view 530 of the thermal switch assembly 500 of FIG. 5A. Thermal switch assembly 500 includes a condenser 532 connected with a vapor return path (e.g., vapor flow) allowing a vapor 538 to pass through, and a cooling liquid reservoir 534. An acoustic droplet generator 533 (such as piezoelectric ceramic) is in contact with cooling liquid reservoir 534. An array of micro-nozzles 536, having a feed side and an exhaust side, contacting cooling liquid reservoir 534 from the feed side and proximate to an evaporation chamber 537 on the exhaust side. Evaporation chamber 537 can be proximate to a heat component 531. Cooling liquid reservoir 534 holds a condensed liquid 535 supplied thereto from condenser 532.

As acoustic droplet generator 533 can be actuated by a control signal (such as an AC sinuous wave signal) (e.g., the thermal switch system receives an on-time), acoustic droplet generator 533 generates acoustic waves which propagate in cooling liquid reservoir 534. When the acoustic waves reach array of micro-nozzles 536, they are focused by the inverted geometry of each micro-nozzle and form a large pressure gradient at the respective exit of each micro-nozzle.

Subsequently, small droplets can be ejected from each exit of the micro-nozzles in the array of micro-nozzles. A thin liquid film can be formed at the cooling surface of the hot component, which results in a large evaporation rate due to the dropwise evaporation. As the droplets evaporate, vapor 538 (for example, steam) can be exhausted from the evaporation chamber due to the large pressure in the chamber. A vapor return path will guide vapor 538 to condenser 532 where vapor 538 condenses back to the cooling liquid. Eventually, the condensed liquid 535 is supplied to cooling liquid reservoir 534, forming a closed loop for the system.

FIG. 6 is an illustration of a block diagram of an example method 600 for implementing the thermal switch system. Method 600 starts at a step 605 and proceeds to a step 610 where a thermal switch system can be provided and made adjacent to a heat component, such as a heat sink, or part of a chip or integrated circuit. The thermal switch system can include a cooling liquid reservoir capable of storing a cooling liquid and an array of micro-nozzles capable of releasing a specific amount of the cooling liquid into the evaporation chamber in the direction of the heat component.

In a step 615, a control signal can be received to indicate an on-time for a generation of an acoustic wave, using an acoustic droplet generator. The acoustic wave can force a specific amount of the cooling liquid to pass through an exit of at least one micro-nozzle in the array of micro-nozzles. The exact amount of cooling liquid can be determined to be released through the array of micro-nozzles during the on-time as the change between on-time and an off-time is extremely fast as compared to the current conventional methods for providing thermal transfer.

In a step 620, thermal energy can be dissipated, as vapor of the cooling liquid, from the heat component. The cooling liquid can form a thin liquid film on the surface of the heat component and thereby absorb the thermal energy from the heat component and subsequently change states to a vapor.

In a step 625, the vapor can be captured using a vapor return path and returned to the cooling liquid reservoir or a cooling liquid tank.

Simultaneously, in parallel, overlap, or subsequent to step 625, a step 630 can receive a control signal off-time for the acoustic droplet generator to stop, stopping additional droplets of cooling liquid from being forced through the at least one micro-nozzle. The stop action can occur very fast, such as under one micro-second. Optionally, step 625 can return to step 615 if another on-time cycle is indicated by the control signal. When no further on-time cycles are indicated by the control signal, then method 600 proceeds to a step 695 and ends.

FIG. 7 is an illustration of a graph of an example HTC 700 between an on-time and an off-time. HTC 700 was developed using test data and it demonstrates the HTC difference between an on-time and an off-time of an array of micro-nozzles. HTC 700 has an x-axis 705 showing the time in seconds and a y-axis 706 showing the HTC. An on-time HTC 710 is significantly higher than an off-time HTC 715. The difference between on-time HTC 710 and off-time HTC 715 is shown by double arrow 720, and in this example on-time HTC 710 is approximately 2400 times better than off-time HTC 715.

FIG. 8 is an illustration of diagrams of example arrays of micro-nozzles 800. Arrays of micro-nozzles 800 demonstrate a sample of the different types of surface structures can be utilized for the array of micro-nozzles. Other structure types can be employed as well. Arrays of micro-nozzles 800 demonstrates a dense pyramid pillar structure 810, a pyramid pillar structure 815, a v-channel structure 825, a multi-layer mesh structure 830, and a micro-channel elevated micromembrane 835.

FIG. 9A is an illustration of a graph of an example temperature maintenance 900 over time. Temperature maintenance 900 is derived from test data and shows the relative steady state temperatures achievable using a variety of on-time/off-time ratios. Temperature maintenance 900 has an x-axis 905 showing time in seconds and a y-axis showing the temperature in Celsius.

A line 910 shows a temperature of about 138° C. and an HTC of 5.7 kW/m²K using an on-time of 25 ms followed by an off-time of 25 ms (repeating for the 150 seconds of the test). A line 915 shows a temperature of about 128° C. and an HTC of 8.3 kW/m²K using an on-time of 30 ms followed by an off-time of 20 ms (repeating for the 150 seconds of the test). A line 920 shows a temperature of about 110° C. and an HTC of 9.7 kW/m²K using an on-time of 40 ms followed by an off-time of 10 ms (repeating for the 150 seconds of the test). A line 925 shows a temperature of about 92° C. and an HTC of 10.5 kW/m²K using an on-time of always on.

FIG. 9B is an illustration of a graph of an example ratio comparison 950 of an on-time to an off-time. Ratio comparison 950 shows how the surface temperature of the heat component varies to the HTC depending on the on-time/off-time ratio. Ratio comparison 950 has an x-axis 955 showing the surface temperature of the heat component in Celsius and a y-axis 956 showing the HTC.

A point 960 shows that when the micro-nozzles are always on, the surface temperature is lowest and has the highest HTC. A point 965 shows the surface temperature rising and the HTC falling when the on-time:off-time ratio is 4:1 (e.g., 4 milliseconds to 1 millisecond). A point 970 shows a further increase in surface temperature and a further reductio in HTC when the on-time:off-time ratio is 3:2. A point 975 shows a higher surface temperature and lower HTC when the on-time:off-time ratio is 1:1. By having an optimum surface temperature as an input, an on-time/off-time ratio can be selected to achieve that surface temperature while minimizing the amount of on-time, which typically causes the most energy consumption.

The temperature of the hot surface (e.g., heat component) as a function of time, is a factor that can be utilized for optimizing the system. Generally, the smaller the on/off cycle time (e.g., the ratio and frequency of the on-time to off-time parameters), the more flexibility there is to control the temperature fluctuation of the system, i.e., the temperature can be increased or reduced on demand at a fast rate. In some aspects, the on/off cycle time can be from 1 millisecond to 10 or 100 seconds. In some aspects, values smaller than this range can be used. In some aspects, values larger than this range can be used.

FIG. 10A is an illustration of a graph of an example optimal actuation ratio 1000. Actuation ratio 1000 shows an optimal range of on-time/off time ratios realized through testing using the disclosed dropwise evaporation techniques. Actuation ratio 1000 shows an x-axis 1005 of the actuation ratio of on-time to off-time of the array of micro-nozzles, and a y-axis 1006 of the HTC range. Area 1010 shows the actuation ratio range that best utilizes the dropwise evaporation techniques, approximately 30% to 40% actuation (e.g., an on-time of 0.3 ms to 0.4 ms and an off-time of 0.7 ms to 0.6 ms). Area 1015 shows a partial dryout region when the actuation ratio is too low (e.g., too little cooling liquid). Area 1020 shows a boiling region when the actuation ratio is too high (e.g., too much cooling liquid).

FIG. 10B is an illustration of a graph of an example comparison 1050 between dropwise evaporation and acoustic boiling. Comparison 1050 plots a testing output from the disclosed techniques (e.g., the dropwise evaporation) and acoustic boiling techniques. Comparison 1050 has an x-axis 1055 showing the superheat value in Celsius. Depending on the cooling liquid utilized, the superheat value will be representative of the cooling liquid. X-axis 1055 shows that the superheat is the surface temperature minus the saturation temperature value of the cooling liquid utilized. A y-axis 1056 shows the HTC. A line 1060 shows the acoustic boiling HTC for various temperature values. A Line 1065 shows the HTC for the dropwise evaporation techniques as disclosed herein, for the same temperature range. Line 1065 shows a significantly higher HTC than line 1060.

FIG. 10C is an illustration of a graph of an example HTC ratio 1080 to a coefficient of performance. HTC ratio 1080 shows a comparison of differing cooling techniques employed in the industry and their resulting coefficient of performance as compared to the new disclosed techniques. The coefficient of performance is the amount of cooling power generated over the amount of power needed to enable that cooling process.

HTC ratio 1080 has an x-axis 1085 showing the HTC and a y-axis 1086 showing the coefficient of performance. An arca 1090 shows the disclosed techniques have a high HTC and a high coefficient of performance in testing. The symbols within area 1090 show approximate data points with area 1090 showing an estimated range. An area 1092 shows the single phase technique having a high HTC and a low coefficient of performance in the industry. An area 1094 shows the spray boiling technique having a range of HTC and a low coefficient of performance in the industry. The symbols within area 1094 show approximate data points with area 1094 showing an estimated range. An area 1096 shows the flow boiling technique having a range of HTC and a range of coefficients of performance in the industry. The symbols within area 1096 show approximate data points with area 1096 showing an estimated range.

FIG. 11 is an illustration of a diagram of an example actuation power comparison 1100. Actuation power comparison 1100 has a diagram showing dropwise evaporation taking place as disclosed herein. A graph 1120 compares the actuation power (e.g., input power or power needed to enable the cooling process) to the heat flux and coefficient of performance.

Graph 1120 has an x-axis 1125 showing the actuation power in milliwatts, a first y-axis 1126 showing the coefficient of performance, and a second y-axis 1127 showing the critical heat flux. Other actuation power values can be utilized in this disclosure, the values presented here are for demonstrating the testing values. Line plot 1130 shows the actuation power for the disclosed techniques plotted against the coefficient of performance. Line plot 1135 shows the actuation power for the disclosed techniques plotted against the critical heat flux. This information can help advise an optimal on-time/off-time ratio by looking at the heat flux and coefficient of performance.

FIG. 12 is an illustration of a diagram of an example micro-nozzle density comparison 1200. Micro-nozzle density comparison 1200 shows how the HTC and coefficient of performance can vary when a density 1210 of the micro-nozzles changes, where the values were derived during testing. In a graph 1220, the factors are plotted. Graph 1220 has an x-axis 1225 showing the density of micro-nozzles, a first y-axis 1226 showing the coefficient of performance, and a second y-axis 1227 showing the HTC. Other micro-nozzle densities can be utilized in this disclosure, the values presented here are for demonstrating the testing values. A bar 1230 shows the coefficient of performance for a density of 400 micro-nozzles per centimeters². A bar 1235 shows the HTC for that density level. A bar 1240 shows the coefficient of performance for a density of 1600 micro-nozzles per centimeters². A bar 1245 shows the HTC for that density level.

FIG. 13 is an illustration of a diagram of an example micro-nozzle diameter comparison 1300. Micro-nozzle diameter comparison 1300 demonstrates various diameters 1310 of the micro-nozzles compared to the coefficient of performance and the HTC. Micro-nozzle diameter comparison 1300 has a graph 1320 with an x-axis 1325 showing the micro-nozzle diameter in micrometers (e.g., microns), a first y-axis 1326 showing the coefficient of performance, and a second y-axis 1327 showing the HTC.

A bar 1330 shows the coefficient of performance for a micro-nozzle of 40 microns. A bar 1335 shows the HTC for the 40 micron diameter micro-nozzle. A bar 1340 shows the coefficient of performance for a micro-nozzle of 80 microns. A bar 1345 shows the HTC for the 80 micron diameter micro-nozzle. A bar 1350 shows the coefficient of performance for a micro-nozzle of 160 microns. A bar 1345 shows the HTC for the 160 micron diameter micro-nozzle. Other diameters for the micro-nozzles can be utilized, whether small or larger. Micro-nozzle diameter comparison 1300 is showing that the diameter can be selected to provide a balanced optimization between the HTC and the coefficient of performance. The diameter, the density, and the actuation power are some factors that can be used to provide a balanced system to achieve the desired optimization of the system.

A portion of the above-described apparatus, systems or methods may be embodied in or performed by various digital data processors or computers, wherein the computers are programmed or store executable programs of sequences of software instructions to perform one or more of the steps of the methods. The software instructions of such programs may represent algorithms and be encoded in machine-executable form on non-transitory digital data storage media, e.g., magnetic or optical disks, random-access memory (RAM), magnetic hard disks, flash memories, and/or read-only memory (ROM), to enable various types of digital data processors or computers to perform one, multiple or all of the steps of one or more of the above-described methods, or functions, systems or apparatuses described herein. The data storage media can be part of or associated with the digital data processors or computers.

The digital data processors or computers can be comprised of one or more GPUs, one or more CPUs, one or more of other processor types, or a combination thereof. The digital data processors and computers can be located proximate each other, proximate a user, in a cloud environment, a data center, or located in a combination thereof. For example, some components can be located proximate the user and some components can be located in a cloud environment or data center.

The GPUs can be embodied on a single semiconductor substrate, included in a system with one or more other devices such as additional GPUs, a memory, and a CPU. The GPUs may be included on a graphics card that includes one or more memory devices and is configured to interface with a motherboard of a computer. The GPUs may be integrated GPUs (iGPUs) that are co-located with a CPU on a single chip. Configured or configured to means, for example, designed, constructed, or programmed, with the necessary logic and/or features for performing a task or tasks.

Portions of disclosed examples or embodiments may relate to computer storage products with a non-transitory computer-readable medium that have program code thereon for performing various computer-implemented operations that embody a part of an apparatus, device or carry out the steps of a method set forth herein. Non-transitory used herein refers to all computer-readable media except for transitory, propagating signals. Examples of non-transitory computer-readable media include, but are not limited to: magnetic media such as hard disks, floppy disks, and magnetic tape; optical media such as CD-ROM disks; magneto-optical media such as floppy disks; and hardware devices that are specially configured to store and execute program code, such as ROM and RAM devices. Configured or configured to means, for example, designed, constructed, or programmed, with the necessary logic and/or features for performing a task or tasks. Examples of program code include both machine code, such as produced by a compiler, and files containing higher level code that may be executed by the computer using an interpreter.

In interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

Those skilled in the art to which this application relates will appreciate that other and further additions, deletions, substitutions and modifications may be made to the described embodiments. It is also to be understood that the terminology used herein is for the purpose of describing particular embodiments only, and is not intended to be limiting, since the scope of the present disclosure will be limited only by the claims. Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, a limited number of the exemplary methods and materials are described herein.

Aspects disclosed herein include:
A. A thermal switch system for controlling heat dissipation of a device, including (1) an array of micro-nozzles, the array of micro-nozzles configured to receive a cooling liquid at an entrance of each micro-nozzle in the array of micro-nozzles and to release the cooling liquid toward the device at an exit of each micro-nozzle, wherein the entrance is larger than the exit, and (2) an acoustic droplet generator located proximate the array of micro-nozzles and configured to acoustically force a portion of the cooling liquid through the entrance of at least one micro-nozzle in the array of micro-nozzles, the acoustic droplet generator further configured to receive a control signal and based thereon control a time and an amount of the cooling liquid forced through the at least one micro-nozzle.
B. A method to control heat dissipation of a device, including (1) providing a thermal switch system, the thermal switch system including (1a) an array of micro-nozzles configured to receive a cooling liquid at an entrance of each micro-nozzle in the array of micro-nozzles, and to release the cooling liquid toward the device at an exit of each micro-nozzle in the array of micro-nozzles, wherein the entrance is larger than the exit, and (1b) an acoustic droplet generator located proximate the array of micro-nozzles and configured to acoustically force a portion of the cooling liquid through the entrance of at least one micro-nozzle in the array of micro-nozzles, and further configured to receive a control signal and based thereon control a time and an amount of the cooling liquid forced through the at least one micro-nozzle, (2) sending a control signal to the acoustic droplet generator, the acoustic droplet generator controlling the time and the amount of the cooling liquid moving through the at least one micro-nozzle, (3) dissipating thermal energy from the device as the cooling liquid forms a liquid film on a surface of the device, absorbs the thermal energy, and changes states to vapor, and (4) capturing the vapor using a vapor return path.

Each of the disclosed aspects in A and B can have one or more of the following additional elements in combination. Element 1: further including an evaporation chamber located proximate the exit of the at least one micro-nozzle, the evaporation chamber configured to receive the cooling liquid from the exit of the at least one micro-nozzle. Element 2: further including a cooling liquid reservoir, the cooling liquid reservoir configured to store the cooling liquid, wherein the cooling liquid reservoir is in contact with the acoustic droplet generator and the array of micro-nozzles. Element 3: further including a cooling liquid tank coupled to the cooling liquid reservoir, the cooling liquid tank configured to hold a quantity of the cooling liquid. Element 4: further including a pump coupled to the cooling liquid tank, the pump configured to pump the cooling liquid from the cooling liquid tank to the cooling liquid reservoir. Element 5: further including a condenser, the condenser configured to receive a vapor, condense the vapor back to the cooling liquid, and return the cooling liquid to the cooling liquid reservoir. Element 6: wherein the vapor is the result of a thermal transfer from the device to the cooling liquid transforming at least a portion of the cooling liquid to the vapor. Element 7: further including a heat component positioned to allow the cooling liquid, after passing through the exit of the at least one micro-nozzle, to contact the heat component enabling a thermal transfer from the heat component to the cooling liquid. Element 8: wherein the heat component includes an integrated circuit. Element 9: wherein the heat component includes a heat sink. Element 10: wherein the heat component is part of the device. Element 11: wherein the acoustic droplet generator is further configured to atomize the cooling liquid thereby allowing the cooling liquid to pass through the exit of the at least one micro-nozzle. Element 12: wherein the acoustic droplet generator is configured to generate an acoustic wave to control the time and the amount of the cooling liquid passing through the exit of the at least one micro-nozzle. Element 13: wherein the acoustic droplet generator is a piezoelectric ceramic layer, wherein the control signal is an electric current directed to the piezoelectric ceramic layer. Element 14: where the piezoelectric ceramic layer is configured to generate an acoustic wave to control the time and the amount of the cooling liquid passing through the exit of the at least one micro-nozzle. Element 15: wherein the exit of each micro-nozzle in the array of micro-nozzles is no greater than 14 micrometers in diameter. Element 16: wherein the cooling liquid is water and the thermal switch system employs cold plate cooling. Element 17: wherein the cooling liquid is a dielectric liquid and the thermal switch system employs embedded cooling. Element 18: wherein one or more micro-nozzles in the array of micro-nozzles has one of a triangular pyramid geometry, a cone geometry, or a tetrahedron geometry. Element 19: wherein the array of micro-nozzles is a first array of micro-nozzles and the device is a first device, and further including a second array of micro-nozzles located proximate the acoustic droplet generator, wherein the exit of each micro-nozzle in the second array of micro-nozzles is directed toward a second device. Element 20: wherein the first array of micro-nozzles and the second array of micro-nozzles employ separate cooling liquid reservoirs. Element 21: wherein the cooling liquid is one of a water, a water with additives, a dielectric fluid, an oil, or a refrigerant. Element 22: wherein the thermal switch system is part of an integrated circuit system. Element 23: wherein the control signal indicates an on-time to initiate a generation of acoustic waves by the acoustic droplet generator, or the control signal indicates an off-time to stop the generation of the acoustic waves. Element 24: wherein the dissipating starts and stops by way of the on-time and the off-time in less than one millisecond. Element 25: wherein the sending, the dissipating, and the capturing repeat using the on-time followed by the off-time.

What is claimed is:

1. A thermal switch system for controlling heat dissipation of a device, including:
an array of micro-nozzles, the array of micro-nozzles configured to receive a cooling liquid at an entrance of each micro-nozzle in the array of micro-nozzles and to release the cooling liquid toward the device at an exit of each micro-nozzle, wherein the entrance is larger than the exit; and
an acoustic droplet generator located proximate the array of micro-nozzles and configured to acoustically force a portion of the cooling liquid through the entrance of at least one micro-nozzle in the array of micro-nozzles, the acoustic droplet generator further configured to receive a control signal and based thereon control a time and an amount of the cooling liquid forced through the at least one micro-nozzle.

2. The thermal switch system as recited in claim 1, further including:
an evaporation chamber located proximate the exit of the at least one micro-nozzle, the evaporation chamber configured to receive the cooling liquid from the exit of the at least one micro-nozzle.

3. The thermal switch system as recited in claim 2, further including:
a cooling liquid reservoir, the cooling liquid reservoir configured to store the cooling liquid, wherein the cooling liquid reservoir is in contact with the acoustic droplet generator and the array of micro-nozzles.

4. The thermal switch system as recited in claim 3, further including:
a cooling liquid tank coupled to the cooling liquid reservoir, the cooling liquid tank configured to hold a quantity of the cooling liquid; and
a pump coupled to the cooling liquid tank, the pump configured to pump the cooling liquid from the cooling liquid tank to the cooling liquid reservoir.

5. The thermal switch system as recited in claim 3, further including:
a condenser, the condenser configured to receive a vapor, condense the vapor back to the cooling liquid, and return the cooling liquid to the cooling liquid reservoir, wherein the vapor is the result of a thermal transfer from the device to the cooling liquid transforming at least a portion of the cooling liquid to the vapor.

6. The thermal switch system as recited in claim 1, further including:
a heat component positioned to allow the cooling liquid, after passing through the exit of the at least one micro-nozzle, to contact the heat component enabling a thermal transfer from the heat component to the cooling liquid.

7. The thermal switch system as recited in claim 6, wherein the heat component includes an integrated circuit.

8. The thermal switch system as recited in claim 6, wherein the heat component includes a heat sink.

9. The thermal switch system as recited in claim 6, wherein the heat component is part of the device.

10. The thermal switch system as recited in claim 1, wherein the acoustic droplet generator is further configured to atomize the cooling liquid thereby allowing the cooling liquid to pass through the exit of the at least one micro-nozzle.

11. The thermal switch system as recited in claim 1, wherein the acoustic droplet generator is configured to generate an acoustic wave to control the time and the amount of the cooling liquid passing through the exit of the at least one micro-nozzle.

12. The thermal switch system as recited in claim 1, wherein the acoustic droplet generator is a piezoelectric ceramic layer, wherein the control signal is an electric current directed to the piezoelectric ceramic layer, and where the piezoelectric ceramic layer is configured to generate an acoustic wave to control the time and the amount of the cooling liquid passing through the exit of the at least one micro-nozzle.

13. The thermal switch system as recited in claim 1, wherein the exit of each micro-nozzle in the array of micro-nozzles is no greater than 14 micrometers in diameter.

14. The thermal switch system as recited in claim 1, wherein the cooling liquid is water and the thermal switch system employs cold plate cooling, or the cooling liquid is a dielectric liquid and the thermal switch system employs embedded cooling.

15. The thermal switch system as recited in claim 1, wherein one or more micro-nozzles in the array of micro-nozzles has one of a triangular pyramid geometry, a cone geometry, or a tetrahedron geometry.

16. The thermal switch system as recited in claim 1, wherein the array of micro-nozzles is a first array of micro-nozzles and the device is a first device, and further including:
a second array of micro-nozzles located proximate the acoustic droplet generator, wherein the exit of each micro-nozzle in the second array of micro-nozzles is directed toward a second device.

17. The thermal switch system as recited in claim 16, wherein the first array of micro-nozzles and the second array of micro-nozzles employ separate cooling liquid reservoirs.

18. The thermal switch system as recited in claim 1, wherein the cooling liquid is one of a water, a water with additives, a dielectric fluid, an oil, or a refrigerant.

19. The thermal switch system as recited in claim 1, wherein the thermal switch system is part of an integrated circuit system.

20. A method to control heat dissipation of a device, comprising:
providing a thermal switch system, the thermal switch system including:
an array of micro-nozzles configured to receive a cooling liquid at an entrance of each micro-nozzle in the array of micro-nozzles, and to release the cooling liquid toward the device at an exit of each micro-nozzle in the array of micro-nozzles, wherein the entrance is larger than the exit; and
an acoustic droplet generator located proximate the array of micro-nozzles and configured to acoustically force a portion of the cooling liquid through the entrance of at least one micro-nozzle in the array of micro-nozzles, and further configured to receive a control signal and based thereon control a time and an amount of the cooling liquid forced through the at least one micro-nozzle;
sending a control signal to the acoustic droplet generator, the acoustic droplet generator controlling the time and the amount of the cooling liquid moving through the at least one micro-nozzle;
dissipating thermal energy from the device as the cooling liquid forms a liquid film on a surface of the device, absorbs the thermal energy, and changes states to vapor; and
capturing the vapor using a vapor return path.

21. The method as recited in claim 20, wherein the control signal indicates an on-time to initiate a generation of acoustic waves by the acoustic droplet generator, or the control signal indicates an off-time to stop the generation of the acoustic waves.

22. The method as recited in claim 21, wherein the dissipating starts and stops by way of the on-time and the off-time in less than one millisecond.

23. The method as recited in claim 21, wherein the sending, the dissipating, and the capturing repeat using the on-time followed by the off-time.
